(19) United States
(12) Patent Application Publication
(10) Pub. No.: US 2010/0173482 A1
(43) Pub. Date: Jul. 8, 2010

(54) METHOD AND APPARATUS FOR FABRICATING IB-IIIA-VIA2 COMPOUND SEMICONDUCTOR THIN FILMS

(75) Inventors: Chia-Chih Chuang, Miaoli County (TW); Yu Huang, Hsinchu City (TW)

Correspondence Address: QUINTERO LAW OFFICE, PC, 615 Hampton Dr, Suite A202, Venice, CA, 90291, US

(73) Assignee: INDUSTRIAL TECHNOLOGY RESEARCH INSTITUTE, Hsinchu (TW)

(21) Appl. No.: 12/502,140

(22) Filed: Jul. 13, 2009

(30) Foreign Application Priority Data
Jan. 7, 2009 (TW) 98100298

(51) Int. Cl. H01L 21/20; C23C 14/54

(52) U.S. Cl. 438/503; 204/298.04; 257/E21.09

(57) ABSTRACT

Methods and apparatus for fabricating IB-IIIA-VIA₂ compound semiconductor thin films are provided. A method for fabricating IB-IIIA-VIA₂ compound semiconductor thin films includes providing a substrate with a precursor film thereover, wherein the precursor film includes elements of group IB and group IIIA. An annealing process is performed on the substrate and the precursor film thereover and forms a group IB-IIIA alloy thin film over the substrate. A surface treatment is performed by transporting ionized group VIA elements to the group IB-IIIA alloy thin film to react therewith to thereby form an IB-IIIA-VIA₂ compound semiconductor thin film.

### CROSS REFERENCE TO RELATED APPLICATIONS

This Application claims priority of Taiwan Patent Application No. 98100298, filed on Jan. 7, 2009, the entirety of which is incorporated by reference herein.

### BACKGROUND OF THE INVENTION

1. Field of the Invention

The present invention relates to fabrication of compound semiconductor thin films, and in particular to methods and apparatuses for fabricating IB-IIIA-VIA₂ compound semiconductor thin films.

2. Description of the Related Art

A silicon solar cell is one of the presently applied solar cells in solar cell technology. Fabrication of silicon solar cells, however, require large factories and much power consumption. Therefore, material costs and fabrication costs for forming silicon solar cells are high. Due to physical limitations of silicon, a thickness of the silicon solar cell is normally not less than 200 μm and a great amount of silicon material is needed for fabrication thereof.

Therefore, new solar cell fabrication techniques have been developed, such as the thin film solar cells incorporating IB-IIIA-VIA₂ compound semiconductor materials such as copper-indium-diselenide (CIS) material or copper-indium-gallium-diselenide (CIGS) material. The IB-IIIA-VIA₂ compound semiconductor materials used in the thin film solar cells have a large light absorbing spectrum range and good reliability. By using IB-IIIA-VIA₂ compound semiconductor materials, thin film solar cells can be fabricated on a substrate of relatively cheaper material than silicon, such as glass, plastic or stainless steel. Thickness of the thin film solar cell, may be reduced by 90% of the thickness of the conventional silicon solar cell.

For conventional IB-IIIA-VIA₂ compound semiconductor thin film fabrication, a layer comprising group IB elements and group IIIA elements or an alloy precursor layer comprising group IB-IIIA elements is first deposited over a substrate by physical vapor deposition (PVD) to form a stacked structure comprising a plurality of elemental sub-layers or an alloy layer. A treatment utilizing selenium reaction or sulfur reaction is then performed to form an IB-IIIA-VIA₂ compound semiconductor thin film.

The above treatment utilizing selenium reaction or sulfur reaction can be achieved by methods such as a co-evaporation method or a two-step method. The co-evaporation method is more suitable for fabrication of a substrate with a top surface less than 30 cm by 30 cm. For larger top surfaces, using the co-evaporation method would substantially increase the costs of required fabrication equipment and make uniformity of the IB-IIIA-VIA₂ compound semiconductor thin film much more difficult.

Meanwhile, for fabrication of IB-IIIA-VIA₂ compound semiconductor thin films by the two-step method, wherein a stacked layer structure comprises group IB elements and IIIA elements or group IB-IIIA elements, alloy is first deposited over a substrate by a sputtering method and a treatment utilizing selenium reaction or sulfur reaction is then performed. Thus, IB-IIIA-VIA₂ compound semiconductor thin films are formed on the substrate. Additionally, the following three methods are conventionally applied sulfur reaction or selenium reaction methods for reacting the group IB elements and the group IIIA element or a group IB-IIIA element alloy containing film with the group VIA elements, thereby forming IB-IIIA-VIA₂ compound semiconductor thin films.

Method 1: The sulfur reaction or selenium reaction is performed by using reaction gases mixed with hydrides such as H₂Se or H₂S and inert gases such as Ar or N₂. For this method, process temperature can be reduced to about 500° C. However, the hydrides used are bio-hazards to humans. Thus, costs are increased and feasibility decreased due to the additional process controls and human security controls that are needed.

Method 2: Solid group VIA elements such as Se or S are disposed in a reaction chamber and are heated to form vaporized Se or S. The formed vaporized Se or S are then reacted with the group IB elements and group IIIA elements, or an alloy containing group IB-IIIA elements to form IB-IIIA-VIA₂ compound semiconductor thin films. However, usage efficiency of the group VIA elements are poor and efficiency of the sulfur reaction and the selenium reaction is poor. Meanwhile, process temperature is about 520-550° C. Also, because atom clusters are required to be decomposed into single atoms prior to reaction, process steps are increased and additional power consumption for decomposition of atom clusters is required. The vaporized group VIA elements may comprise single atoms such as Se or S, and atom clusters such as Se2, Se6, Se8, S2, S6 or S8.

Method 3: A vacuum process is performed, to generate single atoms or atom cluster of group VIA elements in a vacuum system. Then the generated single atoms or atom cluster of group VIA elements are reacted with group IB elements and group IIIA elements, or an IB-IIIA alloy formed over the substrate. This method improves usage efficiency of the group VIA elements but the reaction efficiency between the group VIA elements and the group IB elements and group IIIA elements, or between group IB-IIIA alloy is still poor.

### BRIEF SUMMARY OF THE INVENTION

Methods and apparatus for fabricating IB-IIIA-VIA₂ compound semiconductor thin films are provided.

An exemplary method for fabricating IB-IIIA-VIA₂ compound semiconductor thin films comprises providing a substrate with a precursor film thereover, wherein the precursor film comprises elements of group IB and group IIIA. An annealing process is performed on the substrate and the precursor film thereover and forms a group IB-IIIA alloy thin film over the substrate. A surface treatment is performed by transporting ionized group VIA elements to the group IB-IIIA alloy thin film to react therewith to thereby form an IB-IIIA-VIA₂ compound semiconductor thin film.

An exemplary apparatus for fabricating IB-IIIA-VIA₂ compound semiconductor thin films comprises a reaction chamber, a pressure control unit connected with the reaction chamber to control a pressure in the reaction chamber, a pedestal disposed in the reaction chamber for supporting at least one substrate, wherein the at least one substrate comprises elements of group IB and group IIIA, a first group VIA element supply unit connecting with the reaction chamber for providing vaporized first group VIA elements into the reaction chamber, and a plasma unit disposed in the reaction chamber for generating a high density plasma region in the plasma unit. In one embodiment, during a reaction in the reaction chamber, the vaporized first group VIA elements flow through the high density plasma region and transform into ionized first group VIA elements, and the ionized first group VIA elements diffuse into the at least one substrate comprising elements of group IB and group IIIA to form a IB-IIIA-VIA₂ compound semiconductor thin film thereover.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a schematic diagram showing an apparatus for fabricating IB-IIIA-VIA₂ compound semiconductor thin films according to an embodiment of the invention;

FIG. 2 is a schematic diagram showing an apparatus for fabricating IB-IIIA-VIA₂ compound semiconductor thin films according to another embodiment of the invention;

FIG. 3 is a schematic diagram showing an apparatus for fabricating IB-IIIA-VIA₂ compound semiconductor thin films according to yet another embodiment of the invention;

FIG. 4 is a schematic diagram showing an apparatus for fabricating IB-IIIA-VIA₂ compound semiconductor thin films according to another embodiment of the invention;

FIGS. 5a and 5b are mass spectrum diagrams showing analysis results of IB-IIIA-VIA₂ compound semiconductor films in the Example 1 and the Comparative Example 1, respectively; and

FIG. 6 is a diagram showing X-ray analysis results of IB-IIIA-VIA₂ compound semiconductor thin films in the Examples 2-4.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

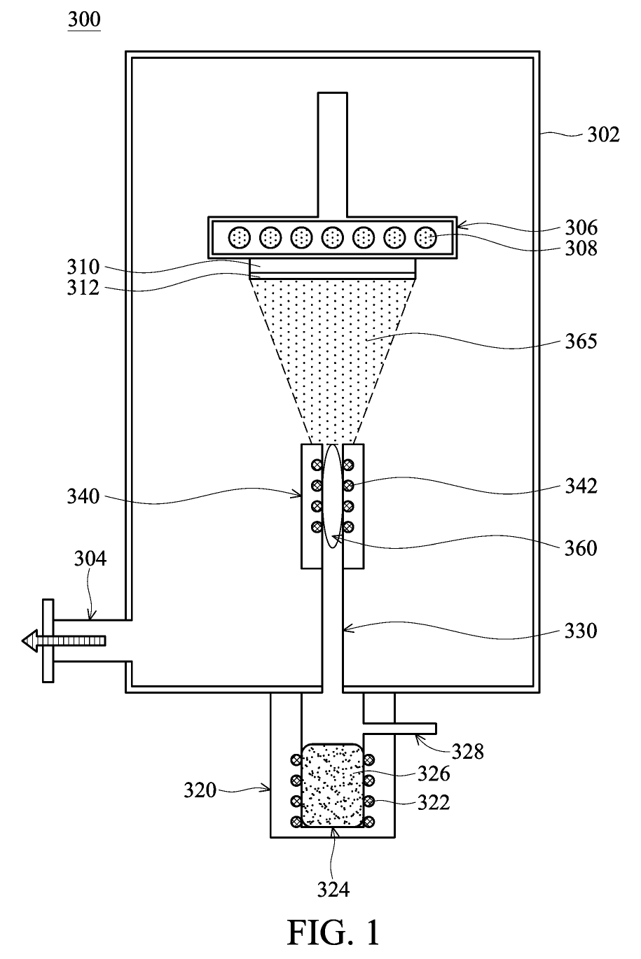

Referring to FIG. 1, an exemplary apparatus 300 for fabricating IB-IIIA-IV₂ compound semiconductor thin films is illustrated. The apparatus 300 includes main components such as a reaction chamber 302, a pressure control unit 304, a pedestal for supporting a substrate 310, a group VIA element supply unit 320 and a plasma unit 340.

During fabrication of IB-IIIA-IV₂ compound semiconductor thin films by using the apparatus 300 illustrated in FIG. 1, a reaction pressure in the reaction chamber 302 is controlled to below a normal pressure, for example a pressure between 5*10⁻⁷˜5*10⁻¹ torr, by the pressure control unit 304. The group VIA element supply unit 320 provides vaporized group VIA elements into the reaction chamber 302 and the vaporized VIA group elements flow through a high density plasma region 360 provided by the plasma unit 340 by the piping 330, thereby forming a group VIA element ions region 365 at a region between the plasma unit 340 and the substrate 310. The vaporized group VIA elements in the group VIA element ion region 365 diffuse into a precursor film 312 comprising a group IB-IIIA alloy thin film or comprising group IB elements and group IIIA elements and react therewith, thereby forming a IB-IIIA-IV₂ compound semiconductor thin film (not shown) over the substrate 310.

As shown in FIG. 1 the reaction chamber 302 may comprise vacuum sustaining materials such as stainless steal or high-temperature standing metal. The pressure control unit 304 is connected with the reaction chamber 302 to control a pressure in the reaction chamber 302 at a range between 5*10⁻⁷ torr to 5*10⁻¹ torr. The pressure control unit 304 may be a low vacuum means such as a rotary pump or a mechanical pump, or a high vacuum mean such as a diffusion pump, cyro-pump or turbine pump.

Still referring to FIG. 1, a temperature control mean 308 can be embedded in the pedestal 306 to control a temperature of the substrate 310 at a range between room temperature to 700° C. The temperature control means 308 can be, for example, a resistance type heating means or a halogen type heating means. The group VIA supply unit 320 connected to the reaction chamber 302 comprises main components such as a group VIA element container 324, a temperature control unit 322 and a carrier gas supply means 328. The group VIA element container 324 may store group VIA elements 326 of solid state, such as solid suffer (S) or selenium (Se). The temperature control mean 322 is embedded in the group VIA supply unit 320 to vaporize the group VIA elements of solid state stored in the group VIA element container 324 during operation, and the carrier gas supply means 328 may supply carrier gases such as nitrogen or other inert gases into the group VIA element container 324 to thereby transport the vaporized group VIA elements into the reaction chamber 302. A plurality of flow meters (not shown) can be provided in the group VIA element supply unit 320 to respectively control a flow rate of the carrier gas into the group VIA element container 324 and a flow rate of the vaporized group VIA elements into the reaction chamber 302.

Still referring to FIG. 1, the plasma unit 340 was disposed in the reaction chamber 302 and is connected to the group VIA element supply unit 320 by the piping 330. A plasma generating means 342 such as a DC glow discharge means, radio frequency discharge means, electron cyclotron resonance means or a microwave means was disposed in the plasma unit 340 to form a high density plasma region 360 in a region of the pipe 330 adjacent to the plasma unit 340, and the vaporized group VIA elements passes through the high energy density plasma region 360 produced by the plasma unit 340 is then transported into the reaction chamber 302, thereby formed an ionized group VIA element region 365 at a region between the plasma unit 340 and the substrate 310. In one embodiment, the vaporized VIA group elements is ionized to form ionized VIA group elements such as Se⁺, Se⁺⁺, S⁺, S⁺⁺ and mixtures thereof.

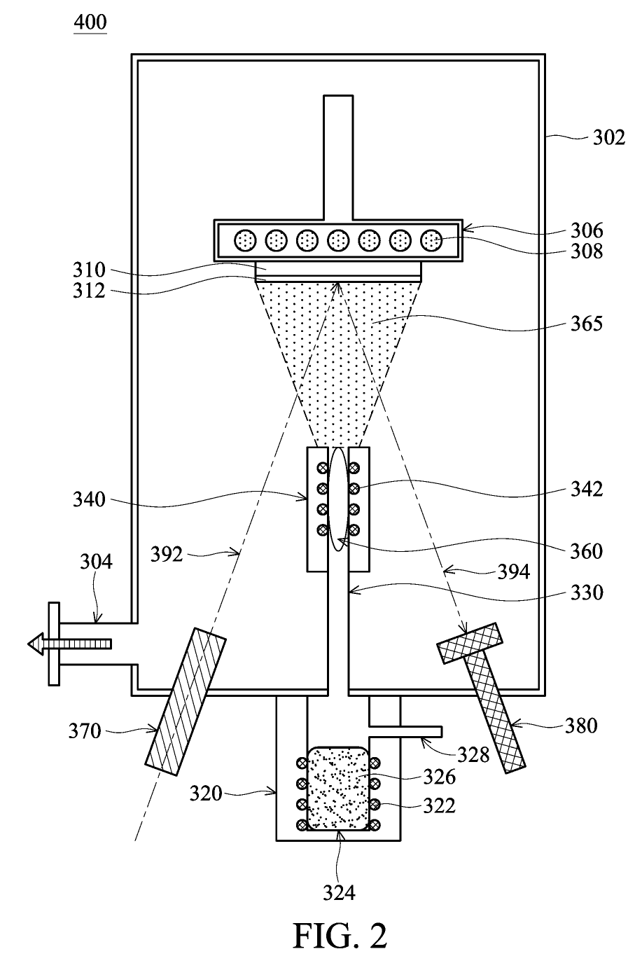

Referring to FIG. 2, another exemplary apparatus 400 for fabricating IB-IIIA-VIA₂ compound semiconductor thin films is illustrated.

As shown in FIG. 2, the apparatus 400 is similar with the apparatus 300 illustrated in FIG. 1. However, the apparatus 400 is further provided with an X ray fluorescent analysis unit comprising an X ray source 370 and a detecting device 380. The X ray source excites X rays 392 and spectrums 394 generated by the X ray 392 at a surface of the substrate 310 is detected by the detecting device 380. Therefore, variation in the ratio and the structure of the precursors such as elements of group IB and IIIA can be effectively monitored during reaction. Thus, real-time process monitoring of the variations in structure and composition of the IB-IIIA-VIA₂ compound semiconductor thin films during the selenium treatment and sulfur treatment thereof, is achieved.

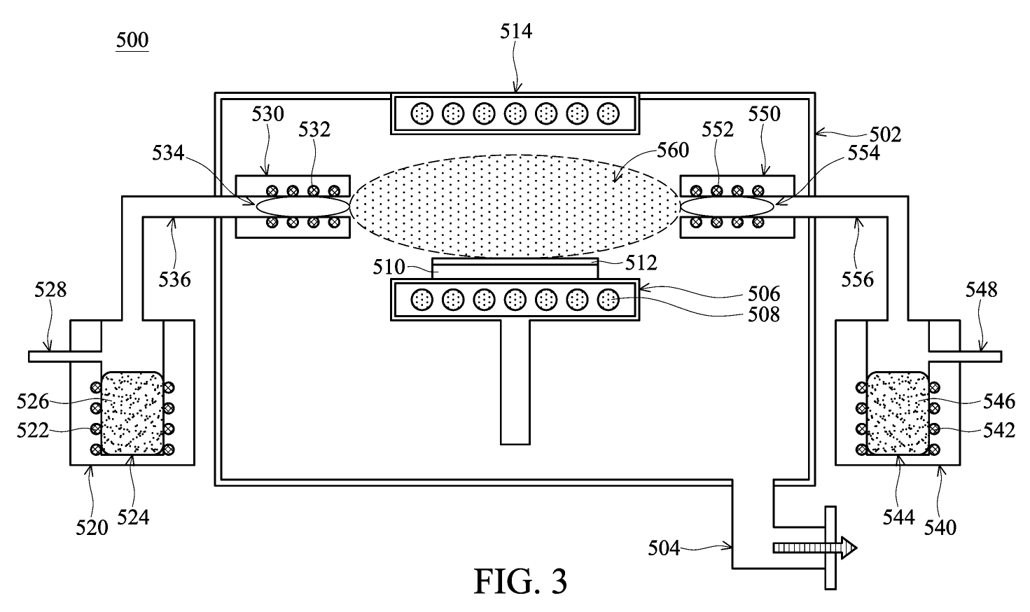

Referring to FIG. 3, yet another exemplary apparatus 500 for fabricating IB-IIIA-VIA₂ compound semiconductor thin films is illustrated.

As shown in FIG. 3, the apparatus 500 is similar with that illustrated in FIG. 1 but an additional group VIA element supply unit, a plasma unit and a temperature controlling device are provided.

Referring to FIG. 3, the apparatus 500 comprises main components such as a reaction chamber 502, a pressure control unit 504, a pedestal 506 for supporting a substrate 510, group VIA element supply units 520 and 540, plasma units 530 and 550. The plasma units 530 and 550 are connected with the group VIA element supply units 520 and 540 through the piping 536 and 556, respectively.

During fabrication of IB-IIIA-VIA₂ compound semiconductor thin films by the apparatus 500, a pressure in the reaction chamber is controlled below a normal pressure, such as a pressure between 5*10⁻⁷-5*10⁻¹ torr, by the pressure control unit 504. The VIA group element supply unit 520 and 540 may provide two different vaporized group VIA elements or more into the reaction chamber 502. These vaporized group VIA elements flow through a high energy density plasma region 534 and 544 formed in the piping 536 and 556 which is generated by the plasma unit 530 and 550, thereby forming group VIA element ion region 560 comprising two or more kinds of ionized group VIA elements. The ionized group VIA elements in the VIA group element ion region 560 diffuse into the substrate 510 and react with the group IB elements and the group IIIA elements in the precursor film 512 formed thereover, thereby forming the IB-IIIA-VIA₂ compound semiconductor thin films. The reaction chamber 502 and the pressure control unit 504 are the same with the reaction chamber 302 and the pressure control unit 304 illustrated in FIG. 1, and embodiments of the reaction chamber 502 and the pressure control unit 504 are not described in detail here again, for simplicity.

Referring to the FIG. 3, a temperature control means 508 is embedded in the pedestal 506 for controlling a temperature of the substrate 510. In this embodiment, another temperature control means 514 was disposed on an opposite side of the reaction chamber 502 for more precisely controlling a reaction temperature in the reaction chamber 502. The temperature control means 508 and 514 are the same with the temperature control means 308 illustrated in FIG. 1 and are not described here again, for simplicity. The temperature control means 508 and 514 can be, for example, a resistance type heating means or halogen type heating means.

Referring to FIG. 3, the group VIA element supply unit 520 connected with one side of the reaction chamber 502 comprises a group VIA element container 524, a temperature control mean 522 and a carrier gas supply mean 528. The group VIA element container 524 may store the group VIA elements 526 of solid state, such as solid Se or S. The temperature control mean 522 is embedded in the group VIA element supply unit 520 to vaporize the group VIA elements 526 of solid state in the group VIA element container 524 during operation. The carrier gas supply mean 528 may supply carrier gases such as nitrogen or other inert gases into the group VIA element container 524, thereby transporting the vaporized group VIA elements (not shown) into the reaction chamber 502. A plurality of flow meters (not shown) can be provided in the group VIA element supply unit 520 to respectively control a flow rate of the carrier gas into the group VIA element container 524 and the vaporized group VIA elements into the reaction chamber 502.

In addition, another VIA group element supply unit 540 is connected with another side of the reaction chamber 502 to thereby transport the group VIA elements different form that supplied by the VIA group element supply unit 520 into the reaction chamber 502. Herein, the group VIA element supply unit 540 comprises a group VIA element container 544, a temperature control mean 542, and a carrier gas supply mean 548. The group VIA element container 544 may store the group VIA elements 546 of solid state, such as solid Se or S. The temperature control mean 542 is embedded in the group VIA element supply unit 540 to vaporize the VIA group elements 546 of solid state and forms vaporized VIA group elements during operation. The carrier gas supply mean 548 may supply carrier gases such as nitrogen or other inert gases into the group VIA element container 544, thereby transporting the vaporized group VIA elements (not shown) into the reaction chamber 502. A plurality of flow meters (not shown) can be provided in the group VIA element supply unit 540 to respectively control a flow rate of the carrier gas into the group VIA element container 544 and the vaporized group VIA elements into the reaction chamber 502. Through the use of the apparatus 500 shown in FIG. 3, IB-IIIA-VIA₂ compound semiconductor thin films comprising two or more different group VIA elements can be formed.

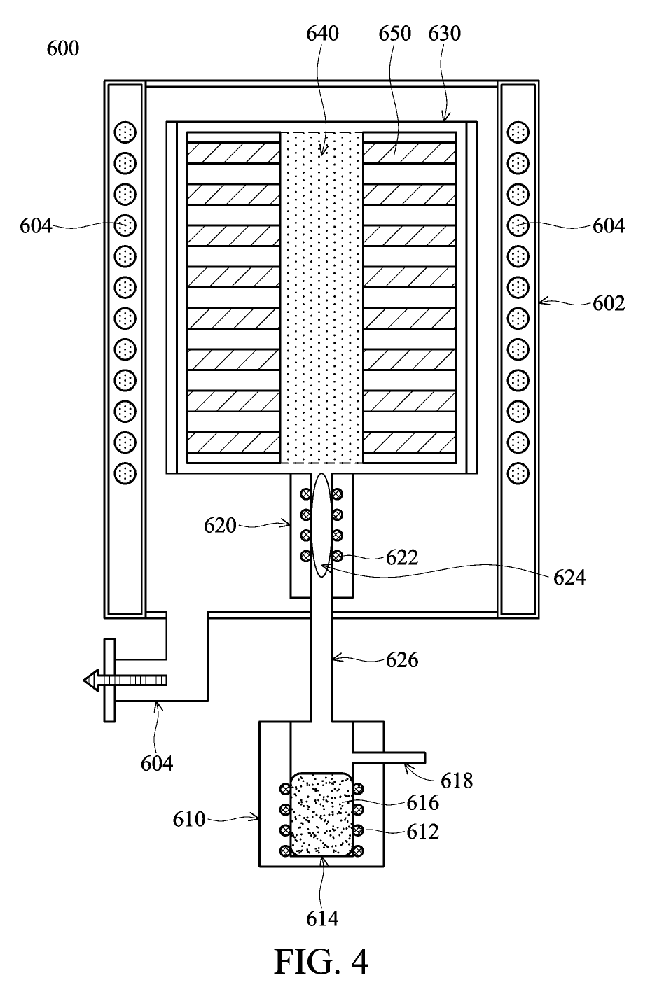

Referring to FIG. 4, another exemplary apparatus 600 for fabricating IB-IIIA-VIA₂ compound semiconductor thin films is illustrated. The apparatus 600 is similar with the apparatus 100 illustrated in FIG. 1 but the pedestal in the apparatus 600 can support a plurality of substrates spaced apart to form IB-IIIA-VIA₂ compound semiconductor thin films on the substrates 650 at the same time. This is convenient for mass production of the IB-IIIA-VIA₂ compound semiconductor thin films.

Referring to FIG. 4, the apparatus 600 comprises main components such as a reaction chamber 600, a pressure control unit 604, a pedestal 630 for supporting a plurality of substrates 650, a group VIA element supply unit 610, a plasma unit 620, and a temperature control mean 604. The plasma unit 620 is connected with the group VIA element supply unit 610 by a piping 626.

During fabrication of IB-IIIA-IV₂ compound semiconductor thin films by using the apparatus 600 illustrated in FIG. 4, a reaction pressure in the reaction chamber 602 is controlled to below a normal pressure, for example a pressure between 5*10⁻⁷˜5*10⁻¹ torr, by the pressure control unit 604. The group VIA element supply unit 620 provides vaporized group VIA elements into the reaction chamber 602 and the vaporized VIA group elements flow through a high density plasma region 624, thereby forming group VIA element ions region 640 at a region in the pedestal 630 where adjacent to the substrates 650. The vaporized group VIA elements in the group VIA element ion region 640 diffuse into the substrates 650, thereby forming an IB-IIIA-IV₂ compound semiconductor thin film (not shown) over each of the substrates 650. The reaction chamber 602 and the pressure control unit 604 are the same with the reaction chamber 302 and the pressure control unit 304 illustrated in FIG. 1, and embodiments of the reaction chamber 602 and the pressure control unit 604 are not described in detail here again, for simplicity.

Still referring to FIG. 4, the temperature control mean 604 in this embodiment is embedded in sidewalls of the reaction chamber 602 and surrounds the pedestal 630, thereby allowing for effectively controlling a reaction temperature for the substrates 650. The temperature control mean 604 can be, for example, a resistance type heating mean or halogen type heating mean.

Still referring to FIG. 4, the group VIA supply unit 610 connected to the reaction chamber 602 comprises main components such as a group VIA element container 614, a temperature control unit 612 and a carrier gas supply means 618. The group VIA element container 614 may store group VIA elements 616 of solid state, such as solid suffer (S) or selenium (Se). The temperature control mean 612 is embedded in the group VIA supply unit 606 to vaporize the group VIA elements of solid state stored in the group VIA element container 614 during operation, and the carrier gas supply means 618 may supply carrier gases such as nitrogen or other inert gases into the group VIA element container 614 to thereby transport the vaporized group VIA elements into the reaction chamber 602. A plurality of flow meters (not shown) can be provided in the group VIA element supply unit 610 to respectively control a flow rate of the carrier gas into the group VIA element container 614 and a flow rate of the vaporized group VIA elements into the reaction chamber 602.

Still referring to FIG. 4, the plasma unit 620 was disposed in the reaction chamber 602 and is connected to the group VIA element supply unit 606. A plasma generating means 622 such as a DC glow discharge means, radio frequency discharge means, electron cyclotron resonance means or a microwave means was disposed in the plasma unit 620 to form a high density plasma region 624 in a region of the pipe 626 adjacent to the plasma unit 620, and the vaporized group VIA elements passes through the high energy density plasma region 624 produced by the plasma unit 620 is then transported into the reaction chamber 602, thereby formed an ionized group VIA element region 640 at a center portion between the substrates 650 located over the pedestal 630. The ionized VIA group elements in the ionized VIA group element region 640 are then reacted with a precursor film (not shown) formed over the substrate 650 and forms an IB-IIIA-VIA2 compound semiconductor thin film over each of the substrate 650. In one embodiment, the vaporized VIA group elements are ionized to form ionized VIA group elements such as Se⁺, Se⁺⁺, S⁺, S⁺⁺ and mixtures thereof.

An exemplary method for fabricating IB-IIIA-VIA2 compound semiconductor films by using one of the apparatus 100, 200, 300 and 400 as illustrated in FIGS. 1-4 is disclosed, comprising providing a substrate (e.g. the substrate 310, 510, 650) with a precursor film (e.g. the precursor film 312, 512) thereover, wherein the precursor film comprises elements of group IB and group IIIA. An annealing process is performed on the substrate and the precursor film thereover by a temperature control mean (e.g. the temperature control mean 308, 508, 514, and 604), forming a group IB-IIIA alloy thin film over the substrate. A surface treatment by use of the temperature control mean (e.g. the temperature control mean 308, 508, 514, and 604) is performed by transporting ionized group VIA elements to the group IB-IIIA alloy thin film to react therewith, thereby forming an IB-IIIA-VIA₂ compound semiconductor thin film.

In one embodiment, the group IB elements used in above method comprise copper (Cu) and the group IIIA elements used in above method comprises indium (In), germanium (Ga), or combinations thereof. The ionized group VIA elements comprises ionized selenium (Se), ionized sulfur (S), or combinations thereof, and the ionized group VIA elements comprise Se⁺, Se⁺⁺, S⁺, S⁺⁺ or combinations thereof.

In one embodiment, the above ionized group VIA elements are formed by transporting vaporized group VIA elements trough a high density plasma formed by a DC glow discharge mean, a ratio frequency discharge mean, an electro cyclotron resonance mean or a microwave mean.

In one embodiment, the above ionized group VIA elements are formed by decomposition under a power of about 100-600 W by a plasma generate mean.

In one embodiment, the above annealing process is performed under a temperature of about 150-400° C. and a pressure of about 1*10⁻⁷-700 torr.

In one embodiment, the above surface treatment is performed under a temperature of about 400-600° C. and a pressure under 1*10⁻⁶-500 torr.

In one embodiment, the above substrate is a glass substrate, a metal substrate, a ceramic substrate, or a polymer substrate and the IB-IIIA-VIA₂ compound semiconductor films formed over the substrate may comprise CuₓIn₁₋ₓSe₂, CuₓGa_{y}Se₂, CuₓIn₁₋ₓGa_{y}Se₂, or CuₓIn₁₋ₓGa_{y}(SSe)₂, and wherein 0<x<1 and 0<y<1.

The apparatus and the method for fabricating IB-IIIA-VIA₂ compound semiconductor films of the invention have the following advantages:

1. A selenium surface treatment or sulfur surface treatment can be performed by using ionized group VIA elements, and efficiency of the selenium reaction or sulfur reaction therein can be improved. Additionally, usages of the selenium or sulfur elements can be reduced by reacting ionized group VIA elements with group IB elements and group IIIA elements, or IB-IIIA group alloys.

2. The surface treatment incorporating the selenium reaction or sulfur reaction is preformed in a vacuum system by using ionized group VIA elements. Thus, usage of highly toxic hydrogen-containing VIA element gases such as H₂Se or H₂S is avoided and costs for process control and hazard control thereof are also reduced.

3. The IB-IIIA-VIA₂ compound semiconductor thin film can be simultaneously formed over a plurality of substrates by the apparatus disclosed in the invention for mass production.

### Embodiment

### Embodiment 1

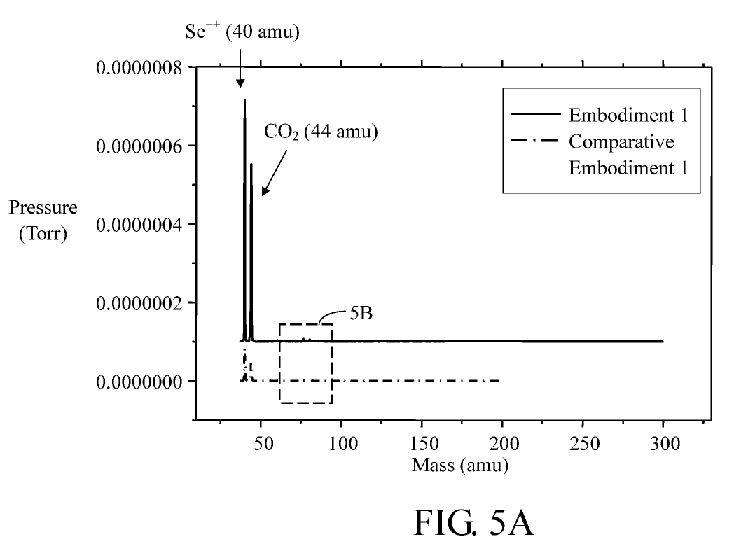

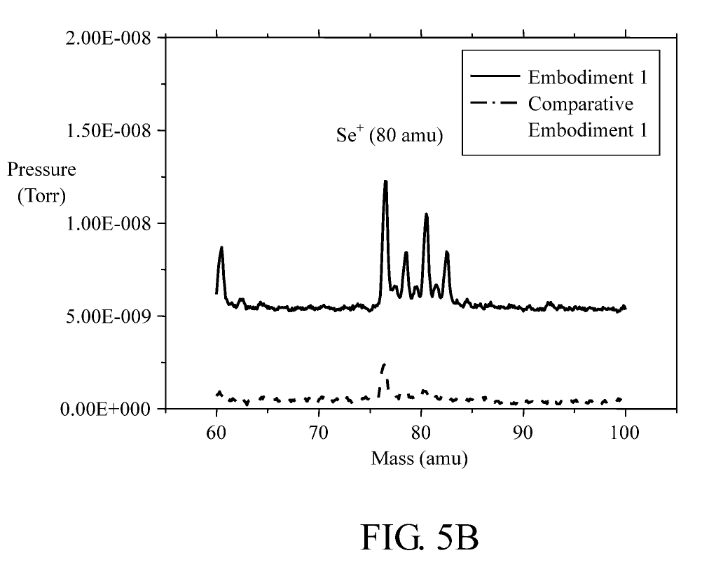

The apparatus 400 illustrated in FIG. 2 was utilized and solid selenium in the group VIA element container 324 was heated from room temperature to 350° C. by the temperature control mean 322, such that vaporized selenium comprising atom clusters such as Se, Se2, Se6, and/or Se8 were generated. Next, a nitrogen flow was provided at a flow rate of about 10 sccm to the group VIA element container 324 by the carrier gas supply mean 328 to transport the vaporized selenium to the high density plasma region 360 generated by the plasma unit 340. The gaseous selenium passed the high density plasma region 360 and was decomposed into the ionized selenium and then reacted with the IB-IIIA alloy formed over the substrate, thereby forming an IB-IIIA-VIA2 compound semiconductor thin film over the substrate. In this embodiment, an efficiency for ionizing the gaseous selenium was analyzed and determined by a residue gas apparatus (RGA, model CIS-300, a product of Stanford Research Systems). Referring to the solid lines illustrated in FIGS. 5a and 5b, an intensity of the Se⁺⁺ ions (38-40 amu) and Se⁺ ions (76-80 amu) were respectively illustrated, having an appearance of about 5.81*10⁻⁷ torr and 5.5*10⁻⁹ torr, respectively.

### Comparative Embodiment 1

The apparatus and method which was the same as that disclosed in Embodiment 1 were utilized. In this embodiment, the plasma unit 340 was turned off and no ionized group VIA element region 365 was formed in the reaction chamber 302, such that the gaseous Se transported into the reaction chamber directly reacting with the substrate 310. After reaction, the substrate was analyzed by an RGA used in Embodiment 1. Referring to the dotted line in FIG. 5a and 5b, an intensity of the Se⁺⁺ ions (38-40 amu) and Se⁺ ions (76-80 amu) were respectively illustrated, having an appearance of about 7.78*10⁻⁸ torr and 8.1*10⁻¹⁰ torr, respectively.

According to the analysis results obtained from the Embodiment 1 and the Comparative Embodiment 1, ionized Se ions (Se⁺⁺ and Se⁺) were obviously increased after the plasma unit was turned on, and the increased ionized Se were generated by plasma ionization and were formed from the atomic clusters (Se2, Se6, Se8) included in the gaseous Se. Thus, the apparatus 400 in FIG. 2 was capable for generating ionized Se to react with the substrate and form IB-IIIA-VIA₂ compound semiconductor thin films thereon.

### Embodiment 2

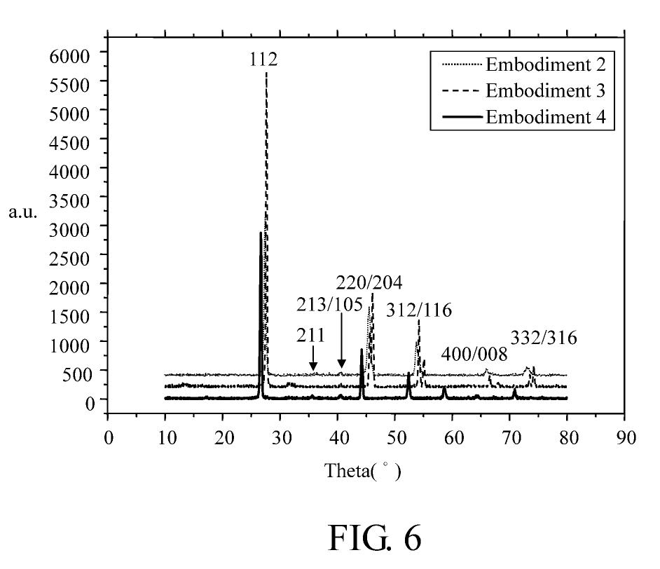

The apparatus 400 shown in FIG. 2 was utilized. A substrate 310 with a precursor film 312 formed thereover was disposed on the pedestal 306. The precursor film 312 was formed over the substrate 310 of glass material by methods such as sputtering, having a Cu_{0.73}Ga_{0.27} film and an In film. Solid Se were disposed in the group VIA element container 324. Next, a pressure control unit sucked air out of the reaction chamber 302 to control a pressure therein at about 1*10⁻⁶ torr, wherein once the pressure was reached, it was maintained at the desired level. At this time, the solid Se and the precursor film 312 having elements of Cu, In, and Ga were heated by the temperature control means 322 and 308. The precursor film 312 was heated to a temperature of 300° C. and held at the temperature for 60 minutes, thereby converting the Cu_{0.73}Ga_{0.27} film and the In film into a CuₓIn₁₋ₓGa_{y} alloy film. Once the solid Se was heated to 200° C., a nitrogen of a flow rate of about 5 sccm was then transported into the group VIA element container 324 by the carrier gas supply unit 328 to transport the vapored Se into the reaction chamber 302. At this time, the solid Se was heated to a temperature of about 350° C. At this time, a pressure in the reaction chamber 302 was elevated to 1*10⁻⁵ torr and an RF power of the plasma generating apparatus 342 was elevated to 300 W for generating a high density plasma region 360 and ionizing the vaporized Se and the nitrogen passing therethrough. Most of the generated Se ions traveled to the surface of the CuₓIn_{1-y}Ga_{y} alloy film and diffused therein. At this time, a CuInGaSe₂ compound was formed since the CuₓIn_{1-y}Ga_{y} alloy film, heated to a temperature of 520° C., reacted with the ionized Se diffused in the CuₓIn_{1-y}Ga_{y} alloy film. After a 60 minute reaction between the CuₓIn_{1-y}Ga_{y} alloy film with the Se ions, a CuInGaSe₂ compound semiconductor thin film was formed. As shown in FIG. 6, formation of the CuInGaSe₂ compound semiconductor thin film is shown following analysis by the X ray analysis unit.

### Embodiment 3

The apparatus 400 shown in FIG. 2 was utilized. A substrate 310 with a precursor film 312 formed thereover was disposed on the pedestal 306. The precursor film 312 was formed over the substrate 310 of glass material by methods such as sputtering, having a Cu_{0.73}Ga_{0.27} film. Solid Se were disposed in the group VIA element container 324. Next, a pressure control unit was used to suck out air from the reaction chamber 302 to control a pressure therein at about 1*10⁻⁶ torr, wherein the pressure was maintained between 1*10⁻⁶ torr and 2*10⁻⁶ torr. At this time, the solid Se and the precursor film 312 having elements of Cu and Ga were heated by the temperature control means 322 and 308. The precursor film 312 was heated to a temperature of 300° C. and held at the temperature for 60 minutes. Once the solid Se was heated to 200° C., a nitrogen of a flow rate of about 5 sccm was then transported into the group VIA element container 324 by the carrier gas supply unit 328 to transport the vaporized Se into the reaction chamber 302. At this time, the solid Se was heated to a temperature of about 350° C. At this time, a pressure in the reaction chamber 302 was elevated to 1*10⁻⁵ torr and a RF power of the plasma generating apparatus 342 was elevated to 300 W for generating a high density plasma region 360 and ionizing the vaporized Se and the nitrogen passing therethrough. Most of the generated Se ions arrived at a surface of the Cu_{0.73}Ga_{0.27} film and diffused therein. At this time, the Cu_{0.73}Ga_{0.27}Se₂ compound was formed since the Cu_{0.73}Ga_{0.27} film was heated to a temperature of 520° C. and reacted with the ionized Se diffused in the Cu_{0.73}Ga_{0.27} film. After a 60 minutes reaction between the Cu_{0.73}Ga_{0.27} film with the Se ions, a Cu_{0.73}Ga_{0.27}Se₂ compound semiconductor thin film was formed. As shown in FIG. 6, formation of the CuGaSe₂ compound semiconductor thin film was confirmed by fluorescent analysis of the X ray analysis unit.

### Embodiment 4

The apparatus 400 shown in FIG. 2 was utilized. A substrate 310 with a precursor film 312 formed thereover was disposed on the pedestal 306. The precursor film 312 was formed over the substrate 310 of glass material by methods such as sputtering, having a Cu_{0.48}In0.52 film. Solid Se were disposed in the group VIA element container 324. Next, a pressure control unit was used to suck out air from the reaction chamber 302 to control a pressure therein at about 1*10⁻⁶ torr, wherein once reached, the pressure was maintained. At this time, the solid Se and the precursor film 312 having elements of Cu an In were heated by the temperature control means 322 and 308. The precursor film 312 was heated to a temperature of 300° C. and held at this temperature for 60 minutes. Once the solid Se was heated to 200° C., a nitrogen of a flow rate of about 5 sccm was then transported into the group VIA element container 324 by the carrier gas supply unit 328 to transport the vaporized Se into the reaction chamber 302. At this time, the solid Se was heated to a temperature of about 350° C. At this time, a pressure in the reaction chamber 302 was elevated to 1*10⁻⁵ torr and an RF power of the plasma generating apparatus 342 was elevated to 300 W to generate a high density plasma region 360 and ionize the vaporized Se and the nitrogen passing therethrough. Most of the generated Se ions arrived at a surface of the Cu_{0.48}In_{0.52} film and diffused therein. At this time, a Cu_{0.48}In_{0.52}Se₂ compound was formed since the Cu_{0.48}In_{0.52} film was heated to a temperature of 520° C. and reacted with the ionized Se diffused in the Cu_{0.48}In_{0.52} film. After a sixty minutes reaction, a Cu_{0.48}In_{0.52}Se₂ compound semiconductor thin film was formed by totally reaction between the Cu_{0.48}In_{0.52} film with the Se ions. As shown in FIG. 6, formation of the CuInSe₂ compound semiconductor thin film is confirmed by fluorescent analysis of the X ray analysis unit.

While the invention has been described by way of Example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for fabricating IB-IIIA-VIA₂ compound semiconductor thin films, comprising:
providing a substrate with a precursor film thereover, wherein the precursor film comprises elements of group IB and group IIIA;
performing an annealing process on the substrate and the precursor film thereover, forming a group IB-IIIA alloy thin film over the substrate; and
performing a surface treatment by transporting ionized group VIA elements to the group IB-IIIA alloy thin film to react therewith, thereby forming a IB-IIIA-VIA₂ compound semiconductor thin film.

2. The method as claimed in claim 1, wherein the group IB elements comprise copper (Cu) and the group IIIA elements comprises indium (In), germanium (Ga), or combinations thereof.

3. The method as claimed in claim 1, wherein the ionized group VIA elements comprises ionized selenium (Se), ionized sulfur (S), or combinations thereof.

4. The method as claimed in claim 1, wherein the ionized group VIA elements comprise Se⁺, Se⁺⁺, S⁺, S⁺⁺ or combinations thereof.

5. The method as claimed in claim 1, wherein the ionized group VIA elements are formed by transporting vaporized group VIA elements trough a plasma.

6. The method as claimed in claim 1, wherein the plasma is a high density plasma formed by a DC glow discharge mean, a ratio frequency discharge mean, an electro cyclotron resonance mean or a microwave mean.

7. The method as claimed in claim 1, wherein the annealing process is performed under a temperature of about 150-400° C. and a pressure of about 1*10⁻⁷-700 torr.

8. The method as claimed in claim 1, wherein the surface treatment is performed under a temperature of about 400-600° C. and a pressure under 1*10⁻⁶-500 torr.

9. The method as claimed in claim 1, wherein the substrate is a glass substrate, a metal substrate, a ceramic substrate, or a polymer substrate.

10. The method as claimed in claim 1, wherein the IB-IIIA-VIA₂ compound semiconductor films comprises CuₓIn₁₋ₓSe₂, CuₓGa_{y}Se₂, CuₓIn₁₋ₓGa_{y}Se₂, or CuₓIn₁₋ₓGa_{y}(SSe)₂, and wherein 0<x<1 and 0<y<1.

11. An apparatus for fabricating IB-IIIA-VIA₂ compound semiconductor thin films, comprising:
a reaction chamber;
a pressure control unit connected with the reaction chamber to control a pressure in the reaction chamber;
a pedestal disposed in the reaction chamber for supporting at least one substrate, wherein the at least one substrate comprises elements of group IB and group IIIA;
a first group VIA element supply unit connecting with the reaction chamber for providing vaporized first group VIA elements into the reaction chamber; and
a plasma unit disposed in the reaction chamber for generating a high density plasma region in the plasma unit,
wherein during a reaction in the reaction chamber, the vaporized first group VIA elements flow through the high density plasma region and transform into ionized first group VIA elements, and the ionized first group VIA elements diffuse into the at least one substrate comprising elements of group IB and group IIIA to form a IB-IIIA-VIA₂ compound semiconductor thin film thereover.

12. The apparatus as claimed in claim 11, wherein the first group VIA element supply unit comprises:
a first group VIA element container for storing the group VIA elements of solid state;
a first temperature control mean embedded in the first group VIA element container for heating the group VIA elements of solid state to form the vaporized group VIA elements; and
a first carrier gas supply mean for providing a first carrier gas into the group VIA element container and transporting the vaporized group VIA elements to the reaction chamber.

13. The apparatus as claimed in claim 11, further comprising:
an X-ray analysis unit connected with the reaction chamber for monitoring, in real-time, a quality of the IB-IIIA-VIA₂ compound semiconductor thin films formed over the substrate.

14. The apparatus as claimed in claim 11, further comprising:
a second VIA group element supply unit connected with the reaction chamber for providing vaporized second group VIA elements different from the vaporized first group VIA elements into the reaction chamber, wherein during a reaction in the reaction chamber, the vaporized first and second group VIA elements flow through the high density plasma region and transform into ionized first and second group VIA elements, and the ionized first and second group VIA elements diffuse into the at least one substrate comprising elements of group IB and group IIIA to form a IB-IIIA-VIA₂ compound semiconductor thin film thereover.

15. The apparatus as claimed in claim 14, wherein the second group VIA element supply unit comprises:
a second group VIA element container for storing the second group VIA elements of solid state;
a second temperature control means embedded in the first group VIA element container for heating the group VIA elements of solid state and forming the vaporized group VIA elements; and
a second carrier gas supply apparatus for providing a second carrier gas to the group VIA element container, thereby transporting the vaporized group VIA elements into the reaction chamber.

16. The apparatus as claimed in claim 11, wherein the reaction chamber is made of stainless steel or high-temperature standing metal materials.

17. The apparatus as claimed in claim 11, further comprising a first temperature control means embedded in the pedestal for controlling a temperature of the substrate.

18. The apparatus as claimed in claim 17, wherein the first temperature control means is a resistance-type heating means or a halogen-type heating means.

19. The apparatus as claimed in claim 17, wherein the first temperature control means controls a temperature of the substrate at a temperature between a room temperature to 1000° C.

20. The apparatus as claimed in claim 12, wherein the first temperature control means is a resistance-type heating means or a halogen-type heating means for controlling a temperature of the first group VIA element unit at a temperature between a room temperature and 600° C.

21. The apparatus as claimed in claim 15, wherein the second temperature control means is a resistance-type heating means or a halogen-type heating means to control a temperature of the second VIA group element unit at a temperature between a room temperature and 600° C.

22. The apparatus as claimed in claim 11, wherein the plasma unit comprises a DC glow discharge mean, a ratio frequency discharge mean, an electro cyclotron resonance mean or a microwave mean.
